(19) United States
(12) Patent Application Publication
(10) Pub. No.: US 2012/0060897 A1
(43) Pub. Date: Mar. 15, 2012

(54) FLUORESCENCE COLLECTOR AND USE THEREOF

(75) Inventors: Jana Bomm, Berlin (DE); Andreas Büchtemann, Potsdam (DE)

(73) Assignee: FRAUNHOFER-GESELLSCHAFT ZUR FORDERUNG DER ANGEWANDTEN FORSCHUNG E.V., Munchen (DE)

(21) Appl. No.: 13/124,284

(22) PCT Filed: Oct. 16, 2009
(86) PCT No.: PCT/EP09/07453

§ 371 Date: Nov. 28, 2011

(30) Foreign Application Priority Data
Oct. 16, 2008 (DE) 10 2008 052 043.8

(51) Int. Cl. H01L 31/055; H01L 31/0232

(52) U.S. Cl. 136/247; 136/257

(57) ABSTRACT

The invention relates to a fluorescence collector for concentrating and converting solar radiation into electrical energy, which collector is constructed from a substrate and at least one polymer- or sol-gel layer as carrier structures for at least one sort of semiconducting nanoparticles and at least one fluorescent dye. The solar radiation is coupled into the collector, reflected internally and then emerges at a defined location at which a photovoltaic cell is disposed. By means of the latter, the conversion of solar into electrical energy is then effected.

The invention relates to a fluorescence collector for concentrating and converting solar radiation into electrical energy, which collector is constructed from a substrate and at least one polymer layer or sol-gel layer as carrier structures for at least one sort of semiconducting nanoparticles and at least one fluorescent dye. The solar radiation is coupled into the collector, reflected internally and then emerges at a defined location at which a photovoltaic cell is disposed. By means of the latter, the conversion of solar into electrical energy is then effected.

There is understood by a conventional fluorescence collector, an optically transparent material of a suitable form, e.g. plate form, in which fluorescent dyes are embedded which absorb the sunlight incident on the large area of the collector, the emitted fluorescent light being concentrated by internal reflection towards the narrow edges of the collector and being converted there by photovoltaic elements, such as e.g. solar cells, into electrical energy. For this purpose, at least one edge of the collector is provided with a photovoltaic cell. The remaining edges and also the underside of the collector are mirror-coated or provided with diffuse reflectors.

Because of their specific properties, fluorescent collectors are suitable, by their principle of action, for photovoltaic use of solar energy. The advantage of fluorescence collectors relative to solar cells alone resides in a cost reduction due to the saving in surface area of comparatively expensive solar cells. In addition, a fluorescence collector is able to capture not only direct but also diffuse sunlight. A further advantage is that the emitted light can be adapted to the spectral sensitivity of the solar cell and no expensive tracking systems are required.

A disadvantage of these conventional fluorescence collectors is however that the dye contained absorbs only a relatively small proportion of the solar radiation and hence a large part of the solar spectrum is not used for photovoltaic current production. In order to remedy this disadvantage, thin polymer layers were doped with a plurality of fluorescence dyes by S. T. Bailey et al. and applied on a transparent substrate (U.S. Pat. No. 4,329,535). Another variant is represented by collector stacks which comprise a plurality of spectrally complementing dyes (DE 41 10 123). In fact a fairly large part of the solar spectrum is hereby captured but dyes which absorb in particular energy-rich UV radiation are not stable long-term. Innovations relative to the described dye concentrators are represented by quantum dot concentrators (U.S. Pat. No. 6,476,312 B1), liquid concentrators (V. Sholin et al., J. Appl. Phys. 2007, 101, 123114) and concentrators comprising semiconducting nanoparticles (U.S. Pat. No. 7,068,898 B2). The described inorganic semiconducting nanoparticles have in fact high long-term stability but it is disadvantageous that the semiconducting nanoparticles absorb predominantly in the UV range, but have only weak absorption in the visible range and consequently a large part of the visible and also of the near infrared spectrum does not contribute, or only slightly, to energy generation. In addition, the semiconducting nanoparticles have only a limited quantum yield; quantum yields of at most 85% are reported for quantum dots by R. Xie et al. in J. Am. Chem. Soc., 2005, 127, 7480-7488, and, by L. Carbone et al. in Nano Letters, 2007, 7, 2942-2950, quantum yields for nanorods of at most 75%. Commercially, e.g. in Sigma-Aldrich and Nanoco Technologies, obtainable semiconducting nanoparticles have however merely quantum yields of 30 to 50%.

A significant problem in the production of nanocomposite materials which comprise fluorescent semiconducting nanoparticles resides in the fact that contact with AIBN initiator radicals during the at present current thermal polymerisation process leads to a reduction in the fluorescence quantum yield (C. Woelfle et al., in Nanotechnology, 2007, 18, 025402).

Starting herefrom, it was the object of the present invention to provide a fluorescence collector which eliminates the described disadvantages in prior art and enables a high quantum yield for the fluorescence radiation.

This object is achieved by the fluorescence collector having the features of claim 1. The further dependent claims reveal advantageous developments. In claim 20, uses according to the invention are described.

According to the invention, a fluorescence collector for concentrating and converting solar radiation into electrical energy is provided, which collector has at least one fluorescent dye, at least one sort of semiconducting nanoparticles and also two carrier structures for the semiconducting nanoparticles and the at least one fluorescent dye. The surface of the fluorescence collector is completely mirror-coated apart from regions intended for the in-coupling of solar light and for the out-coupling of the fluorescence radiation or has diffuse reflectors so that internal reflection of the solar radiation entering into the collector is made possible. At the out-coupling region, at least one photovoltaic cell for converting the out-coupled radiation into electrical energy is disposed. The semiconducting nanoparticles and the at least one fluorescent dye are thereby disposed in carrier structures which are separated from each other. The carrier structures are preferably transparent or formed from transparent materials. Carrier structures can thereby be polymer layers, sol-gel layers or coatings, liquids or the substrate, the substrate being able also to be undoped in the case of a multilayer hybrid collector. Because of the possible multilayer or multi-coating construction, any combinations are possible here provided that both semiconducting nanoparticles and fluorescent dye are not integrated in the same carrier structure.

The present invention hence describes the combination of fluorescent dyes with semiconducting nanoparticles. The long-term stable semiconducting nanoparticles which are highly absorbent in the UV range are thereby combined with fluorescent dyes which have high quantum yields of >90%. An energy transfer between the spectrally complementary semiconducting nanoparticles and fluorescent dyes is expressly desired.

It is shown surprisingly that it is possible according to the invention to avoid the above-represented disadvantages of known fluorescence collectors. An essential advantage of the present invention relative to the collectors known from prior art is that almost all spectral ranges of the incident sunlight (UV, VIS, NIR) are used for photovoltaic current production. A further advantage according to the invention in addition is that the semiconducting nanoparticles can be embedded in the corresponding matrix without a polymerisation process and therefore without radicals. Unexpectedly, it could be achieved in addition with a UV polymerisation that the fluorescence quantum yield remains almost unimpaired by the polymerisation reaction. During the combination of one or more fluorescent dyes with at least one sort of semiconducting nanoparticles, the separation of semiconducting nanoparticles and fluorescent dyes appears necessary, i.e. the semiconducting nanoparticles and fluorescent dyes should not be combined in one and the same carrier structure. It had emerged in fact surprisingly that the combination of fluorescent dyes and semiconducting nanoparticles in one and the same carrier structure can lead to destruction of the dye since semiconducting nanoparticles can obviously also act as photocatalysts (P. K. Khanna et al., Journal of Luminescence, 2007, 127, 474-482).

The at least one polymer layer or coating is preferably formed from a transparent polymer. This is preferably selected from the group consisting of poly(meth)acrylates, polystyrene, polycarbonates, silicones and cellulose esters, e.g. cellulose triacetate, and copolymers thereof There are possible as sol-gel layer or coating, transparent sol-gel materials, in particular based on silicon, titanium, zirconium and/or aluminium.

The substrate is formed preferably from a material selected from the group consisting of polymers, such as e.g. poly(meth)acrylates, polystyrene, polycarbonates, silicones, cellulose esters and copolymers thereof, in particular polymethylmethacrylates; glasses, in particular soda-lime glass, borosilicate glass and/or quartz glass; at least one sol-gel coating based on silicon, titanium, zirconium and/or aluminium and/or liquids.

There should be understood by transparent, with respect to the carrier structures, i.e. for example both with respect to the substrate and the polymer- or sol-gel layers or coatings, within the scope of the present invention, that these are permeable for incident and emitted light in a range of 250 to 2,500 nm, in particular of 250 to 1,500 nm over a few 100 nm.

The carrier structures which are doped with at least one fluorescent dye can comprise preferably also additives, such as e.g. radical interceptors, or antioxidants which lead to an increase in the dye stability.

All dyes which have a fluorescence quantum yield of >90%, preferably >95%, particular preferred >99%, are suitable as fluorescent dyes. The dyes should have as high a photostability as possible, i.e. after one year, preferably after 2 years, particularly preferred after three and more years, they should have a residual fluorescence of >50%, preferably >70%, particularly preferred >90%. For example some perylene diimides of the Lumogen F series by BASF prove to be suitable fluorescent dyes.

The semiconducting nanoparticles can vary in their size, shape or their chemical composition, e.g. quantum dots/-rods/multipods, e.g. CdSe, CdS, or core/shell quantum dots/-rods/multipods, e.g. CdSe/ZnS, CdSe/CdS, CdS/ZnS, or core/multishell quantum dots/-rods/multipods, such as e.g. CdSe/CdS/ZnS or CdSe/CdSₓZnS₁₋ₓ/ZnS or CdS/CdSₓZnS₁₋ₓ/ZnS. The shell should have a larger band gap than the core. In the case of multipods, the centre and the arms, and also the arms mutually, can be constructed from different semiconducting materials. The chemical composition can thereby vary also within one arm.

Semiconducting nanoparticles preferably consist of materials which are constructed from an element of the 2^{nd} or 12^{th} group and an element of the 16^{th} group of the periodic table, e.g. CdSe, CdS, ZnS, or of an element of the 13^{th} and an element of the 15^{th} group of the periodic table, e.g. GaAs, InP, InAs, or comprise an element of the 14^{th} group of the periodic table, e.g. PbSe. The particles must be crystalline, monocrystalline or predominantly crystalline or monocrystalline. The semiconducting nanoparticles must display the “quantum-size” effect, i.e. the semiconducting nanoparticles must be of the order of magnitude of the Exciton Bohr radius, consequently the band gap and the emitted fluorescent light can be controlled directly via the particle size and geometry. Quantum dots are thereby spherical particles, quantum rods (nanorods) are particles of a rod-shaped construction, i.e. the length and the diameter thereof are different. Multipods, e.g. tripods, tetrapods, have a centre from which at least two arms (dipods) emanate. Each arm has the characteristic properties of nanorods. The aims can be of equal or different length and can have different diameters, the diameter not requiring absolutely to be constant along one arm. The centre can thereby consist of a different semiconducting material from the arms, which likewise can have a different crystal structure from the centre. The crystal structure and the semiconducting material of which the arms consist can be different for each arm and also vary within one arm.

For better incorporation in polymers, the surface of the semiconducting nanoparticles preferably can be modified with surface ligands, such as e.g. amines, carboxylates, phosphines, phosphine oxides, thiols, mercaptocarboxylic acids, thiol alcohols, amino alcohols, monomers or polymers. The ligands can be present adsorbed or bonded anionically, cationically or covalently to the surface of the semiconducting nanoparticle. They must cover at least a part of the surface of the semiconducting nanoparticle.

According to the invention, different variants for the construction of the fluorescence collectors are preferred.

A first preferred variant provides that the collector consists of a hybrid collector. There is understood by hybrid collectors, a transparent substrate (e.g. glass or Plexiglas) which is doped with at least one fluorescent dye or nanoparticles and on which a polymer- or sol-gel layer is applied, which comprises at least one sort of semiconducting nanoparticles or a fluorescent dye.

The possibility likewise exists that the hybrid collectors have a multilayer construction. There is understood by multilayer hybrid collectors, a plurality of carrier substrates which are layered one above the other, e.g. transparent substrate, e.g. a glass or polymer, e.g. Plexiglas, or a transparent substrate doped with at least one fluorescent dye, e.g. a polymer, such as Plexiglas, on which a plurality of polymer layers is applied and which comprise different fluorescent substances, e.g. fluorescent dyes, semiconducting nanoparticles, the possibility of partial layer penetration existing. At least one polymer layer must comprise at least one sort of semiconducting nanoparticles. The polymer layers can also comprise at least one fluorescent dye.

A second variant provides that the collector consists of a collector stack. A collector stack is an arrangement (stack) of a plurality of collector plates and/or hybrid collectors. Collector plates are polymer layers or polymer plates which comprise at least one sort of semiconducting nanoparticles or at least one fluorescent dye. Collector stacks combine one or more polymer plates and/or hybrid collectors which comprise at least one sort of semiconducting nanoparticles with at least one collector plate and/or hybrid collectors which comprise one or more fluorescent dyes. A polymer plate should have a thickness between 0.5 to 10 mm, preferably 1 to 5 mm. The collector stack thereby comprises preferably a plurality of solar cells.

A further variant provides that the collector consists of a liquid-solid collector, the substrate being formed from an encapsulated glass box, in the cavity of which semiconducting nanoparticles dispersed in a solvent are contained, at least one polymer layer which is doped with one or more fluorescent dyes being applied on the substrate. The encapsulation of the glass box can be effected by means of a suitable adhesive, e.g. epoxide resin adhesive, or by means of a glass solder (low-melting glass).

A polymer- or sol-gel layer preferably has a thickness in the range of 10 nm to 10 mm.

The substrate preferably has a thickness in the range of 0.5 to 10 mm, preferably from 3 to 5 mm. Preferably, the substrate and the at least one polymer layer have an essentially identical refractive index, i.e. the refractive indices differ at most by 0.2 so that the interface or interfaces to the ambient air are intended for total reflection of the emitted light.

The fluorescence collectors according to the invention preferably are provided at one edge with a photovoltaic cell, e.g. a solar cell which serves to produce electrical energy. It should be coupled to the collector via as high-refractive a contact medium as possible. The remaining edges and also the underside of the collector are mirror-coated or provided with a diffuse reflection coating. On the upperside of the collector, a special band-stop filter, e.g. a photonic crystal coating, can be applied, which is as transparent as possible for incident light but, by reflection, prevents or at least greatly reduces as far as possible the exit of emitted long-wave shifted fluorescence light.

In addition to converting solar radiation into electrical energy, the fluorescence collectors according to the invention, in conjunction with solar-thermal plants, can be used for simultaneously obtaining thermal energy. The absorbed energy which is emitted not in the form of emitted light but in the form of heat can thereby be removed by a heat transfer material, e.g. water/glycol mixtures. The thus obtained thermal energy can be used for example for water heating or for converting thermal energy into other energy forms, e.g. electrical, mechanical or chemical energy.

The subject according to the invention is intended to be explained in more detail with reference to the subsequent examples and Figures without wishing to restrict said subject to the special embodiments shown here.

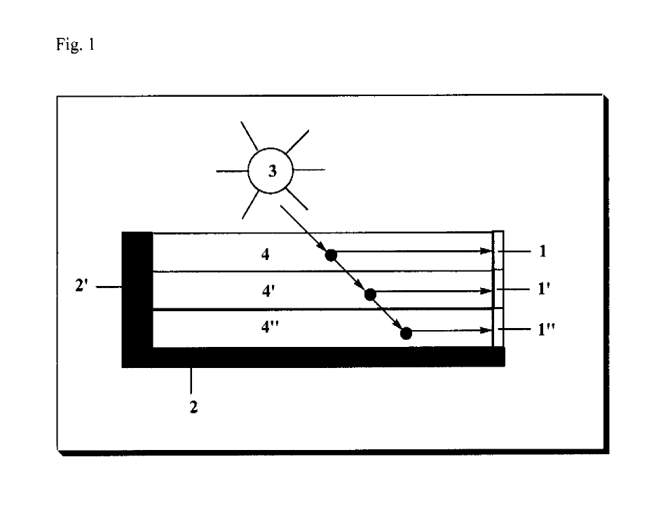

FIG. 1 shows a first variant according to the invention in the form of a collector stack.

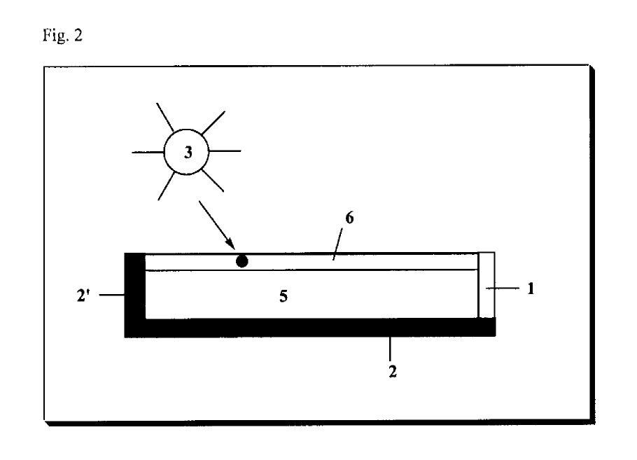

FIG. 2 shows a second variant according to the invention in the form of a hybrid collector.

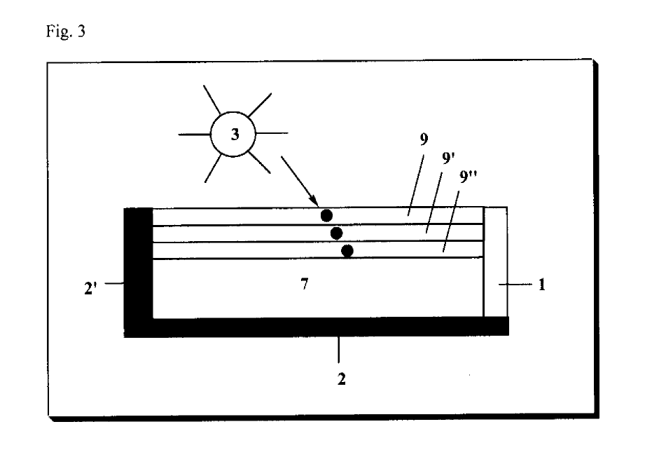

FIG. 3 shows a third variant according to the invention in the form of a multilayer hybrid collector.

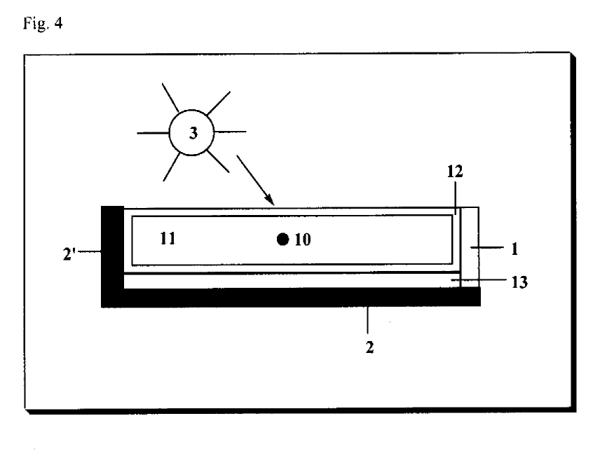

FIG. 4 shows a fourth variant according to the invention in the form of a liquid-solid hybrid collector.

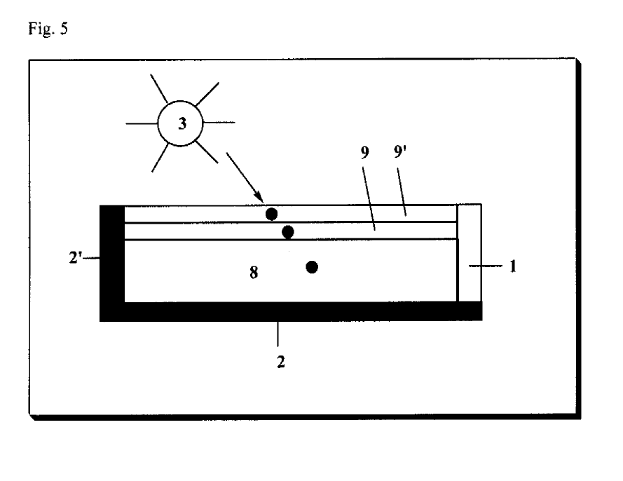

FIG. 5 shows a fifth variant according to the invention in the form of a multilayer hybrid collector.

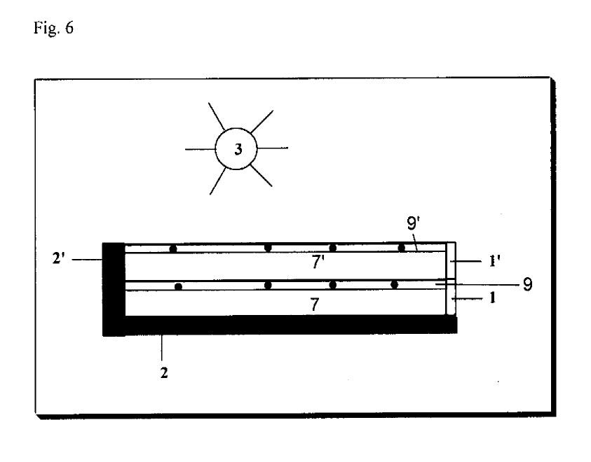

FIG. 6 shows a sixth variant according to the invention in the form of a two-layer hybrid collector.

In FIG. 1, a variant of a fluorescence collector according to the invention which is based on a collector stack is represented. The polymer plates 4, 4′ and 4″ are hereby stacked one above the other. At the same time, the collector has diffuse reflection coatings or mirror-coatings 2 and 2″ on the underside and on three edges of the polymer plate. On the other side of the polymer plates, solar cells 1, 1′ and 1″ for converting the solar radiation 3 into electrical energy are disposed.

In FIG. 2, a further variant according to the invention is represented, in the case of which a substrate 5 is coated with a polymer layer 6 on the side orientated towards the solar radiation. In the polymer- or sol-gel layer 6, the semiconducting nanoparticles are contained and in the substrate of the fluorescent dye. The underside and the three edges of the collector have a mirror-coating 2 or 2′ which can likewise also be a diffuse reflection coating.

In FIG. 3, a further variant according to the invention which is based on a multilayer hybrid collector is represented. This consists of an undoped transparent substrate 7. Further polymer layers 9, 9′ and 9″ in which at least one fluorescent dye and one sort of semiconducting nanoparticles are contained are deposited on the substrate. The semiconducting nanoparticles and the fluorescent dye are thereby situated in different layers.

In FIG. 4, a variant of the collector according to the invention which is based on a liquid-solid hybrid collector is represented. The semiconducting nanoparticles 10 are hereby encapsulated in a solvent 11 in the substrate 12. The substrate here consists for example of a glass box, the encapsulation of the glass frame being able to be effected by means of an adhesive, e.g. an epoxide resin adhesive, or a glass solder. Furthermore, the collector illustrated here has a polymer layer 13 which is doped with the fluorescent dye. The mirror-coatings 2 and 2″ here are again also a component of the collector just as the solar cell 1.

In FIG. 5, a further variant according to the invention which is based on a multilayer hybrid collector is represented. The latter consists of a transparent substrate which is doped with at least one fluorescent dye and on which polymer layers 9, 9′ comprising semiconducting nanoparticles are deposited. Also the variant described in FIG. 5 has a mirror-coating or diffuse reflection coatings on the underside and on three edges of the collector.

In FIG. 6, a further variant according to the invention which is based on a two-layer hybrid collector is represented. This comprises two undoped substrates 7 and 7′ and also two coatings 9 and 9′ which comprise the fluorescent dye or the nanoparticles. The two substrate layers 7 and 7′ are thereby separated from each other by a coating 9 comprising the fluorescent dye or the nanoparticles, whilst the second layer 9′ is applied on the above-situated substrate 7′. In this embodiment, either the coating 9 can comprise nanoparticles or the fluorescent dye; the same applies to the coating 9′. The fluorescence collector represented in this embodiment has two solar cells 1 and 1′ which are disposed on the non-mirror-coated end of the fluorescence collector. The remaining sides have a mirror-coating 2, 2′.

Example of the Production of Collector Stacks:

### EXAMPLE 1

Lauryl methacrylate (LMA), 20% ethylene glycol dimethacrylate (EGDM) and 0.1% of the UV initiator Darocure 4265 are weighed out together with 0.025 to 1.0% CdSe core/multishell quantum dots or CdSe core/shell nanorods and are homogenised by means of agitation and a sonotrode. The batch is filtered over a 5 μm PTFE spray filter into a cuvette with a size of up to 10 cm×10 cm×0.5 cm and is degassed at 200 mbar in a vacuum drying cupboard. The UV polymerisation is implemented for 10 min under nitrogen flushing. The plate is taken out of the cuvette and post-polymerised for 1 to 2 hours under UV radiation.

A cuvette thereby consists of two glass plates and a fluoroethylene polymer seal which serves as spacer for the two glass plates. The cuvette is held together with a metal clamp.

Examples of the Production of Different Hybrid Collectors:

### EXAMPLE 2

0.5 to 2.0% of the CdSe core/shell nanorods or 0.25 to 5.5% of the CdSe core/multishell quantum dots are dispersed in a 2.5% cellulose triacetate/CH₂Cl₂/CHCl₃ solution by means of agitation and ultrasound. 2 to 4 ml of the solution are applied on a glass (5 cm×5 cm×0.3 cm). The polymer coating is left to dry at room temperature.

### EXAMPLE 3

0.75 to 2.0% of the CdSe core/multishell quantum dots and/or of the CdSe core/shell nanorods are dispersed in a 10% PMMA/CHCl₃ solution by means of agitation and ultrasound. 2 to 4 ml of the solution are applied on glass or Plexiglas (5 cm×5 cm×0.3 cm) or on a PMMA plate doped with Lumogen F Red 305. The polymer coating is left to dry at room temperature.

Examples of the Production of Different Multilayer Hybrid Collectors:

### EXAMPLE 4

Firstly, a coating with 1% of the fluorescent dye Lumogen F Red 305 is produced, the dye being dissolved in a 10% PMMA/CHCl₃ solution and 3 ml of the solution being applied on a glass (5 cm×5 cm×0.3 cm). The coating is left to dry overnight at room temperature and temperature-controlled subsequently for 30 min at 60° C. Subsequently, 1% CdSe core/shell nanorods are dispersed in a 7% PMMA/CHCl₃ solution with the help of a sonotrode. 2 g of the solution are applied on the F Red/PMMA coating. After the coating has dried, the sample is temperature-controlled for 30 min at 60° C.

### EXAMPLE 5

Firstly, a coating with 1% of the fluorescent dye Lumogen F Red 305 is produced, the dye being dissolved in a 10% PMMA/CHCl₃ solution and 3 ml of the solution being applied on a glass (5 cm×5 cm×0.3 cm). The coating is left to dry overnight at room temperature and temperature-controlled subsequently for 30 min at 60° C. Subsequently, CdSe core/multishell quantum dots (1% with respect to the PMMA dry material) are dispersed in a 9% PMMA/CHCl₃ solution by means of ultrasound. 2 g of the QD/PMMA/CHCl₃ solution are applied on the F Red/PMMA coating and, after the solvent has evaporated, the coating is temperature-controlled for 30 min at 60°. Subsequently, CdSe core/shell nanorods (1% with respect to the PMMA dry material) are dispersed in a 7% PMMA/CHCl₃ solution with the help of a sonotrode. 2 g of the solution are applied on the F Red/QD/PMMA coating. The coating is temperature-controlled after drying likewise for 30 min at 60° C.

The percentage data of the fluorescent particles, indicated in the examples, should be understood as percent by weight relative to the polymer dry material.

1. A fluorescence collector for concentrating and converting solar radiation into electrical energy, comprising at least one fluorescent dye, at least one sort of semiconducting nanoparticles and at least two carrier structures for the semiconducting nanoparticles and the at least one fluorescent dye, the surface of the fluorescence collector being completely mirror-coated apart from the regions intended for the in-coupling of solar light and for the out-coupling of the fluorescence radiation or having diffuse reflectors in order to enable internal reflection of the solar radiation entering into the collector and, at the out-coupling region, at least one photovoltaic cell for converting the out-coupled radiation into electrical energy being disposed, wherein
the semiconducting nanoparticles and the at least one fluorescent dye are disposed in carrier structures which are separated from each other.

2. The fluorescence collector according to claim 1, wherein the at least two carrier structures are formed from a transparent material.

3. The fluorescence collector according to claim 1, wherein the at least two carrier structures are formed from
a) at least one substrate made of polymer;
b) at least one substrate made of glass;
c) at least one liquid;
d) at least one polymer coating made of a transparent polymer; and/or
e) at least one sol-gel coating; and/or
f) combinations hereof.

4. The fluorescence collector according to claim 3, wherein a substrate is undoped.

5. The fluorescence collector according to claim 1, wherein the carrier structures have further additives.

6. The fluorescence collector according to claim 1, wherein the fluorescence collector, as at least two carrier structures comprises a substrate which is formed from a transparent material and further comprises at least one polymer- or sol-gel coating.

7. The fluorescence collector according to claim 1, wherein the at least one fluorescent dye has a fluorescence quantum yield of at least 90%.

8. The fluorescence collector according to claim 1, wherein the semiconducting nanoparticles consist of elements of the 2^{nd} or 12^{th} group of the periodic table with elements of the 16^{th} group of the periodic table, of elements of the 13^{th} group of the periodic table with elements of the 15^{th} group of the periodic table, or of elements of the 14^{th} group of the periodic table with elements of the 16^{th} group of the periodic table, or comprise a combination of these elements.

9. The fluorescence collector according to claim 1, wherein ligands are adsorbed on the surface of the semiconducting nanoparticles or are bonded covalently or ionically.

10. The fluorescence collector according to claim 1, wherein the collector consists of a hybrid collector which has a transparent substrate comprising at least one fluorescent dye or at least one sort of semiconducting nanoparticles and a carrier structure which comprises semiconducting nanoparticles or at least one fluorescent dye.

11. The fluorescence collector according to claim 10, wherein the hybrid collector has a multilayer configuration or comprises at least one transparent undoped substrate and at least two carrier structures.

12. The fluorescence collector according to claim 1, wherein the collector consists of a collector stack with a plurality of photovoltaic cells which is constructed from at least two carrier structures and/or hybrid collectors, different fluorescent dyes and/or semiconducting nanoparticles being able to be disposed in the individual carrier structures.

13. The fluorescence collector according to claim 12, wherein the collector stack consists of at least two undoped substrates, on the upper side of which at least one carrier structure which comprises the fluorescent dye or the nanoparticles is applied.

14. The fluorescence collector according to claim 1, wherein the collector consists of a liquid-solid collector, the substrate consisting of an encapsulated glass box in which semiconducting nanoparticles which are dispersed in a transparent solvent are contained as carrier structure, and the substrate is combined with at least one polymer layer which comprises at least one fluorescent dye.

15. The fluorescence collector according to claim 14, wherein the at least one carrier structure has a thickness in the range of 10 nm to 10 mm.

16. The fluorescence collector according to claim 15, wherein the substrate has a thickness in the range of 0.5 to 10 mm.

17. The fluorescence collector according to claim 1, wherein the substrate and the at least one carrier structure and the carrier structures mutually have essentially the same refractive index.

18. The fluorescence collector according to claim 1, wherein the at least one photovoltaic cell is connected to the collector at one edge of the collector by means of a high-refractive contact medium.

19. The fluorescence collector according to claim 1, wherein the collector, on the surface orientated towards the solar radiation, has a band-stop filter.

20. A method for converting solar energy into electrical energy and/or in solar-thermal plants comprising utilizing the fluorescence collector according to claim 1.
